(19) United States
(12) Patent Application Publication
(10) Pub. No.: US 2019/0189482 A1
(43) Pub. Date: Jun. 20, 2019

(54) TRANSFER DEVICE, TRANSFER METHOD, AND INSPECTION SYSTEM

(71) Applicant: TOKYO ELECTRON LIMITED, Tokyo (JP)

(72) Inventors: Tadashi OBIKANE, Nirasaki-shi, Yamanashi (JP); Minoru UCHIDA, Nirasaki-shi, Yamanashi (JP)

(73) Assignee: TOKYO ELECTRON LIMITED, Tokyo (JP)

(21) Appl. No.: 16/311,499

(22) PCT Filed: May 11, 2017
(86) PCT No.: PCT/JP2017/017857

§ 371 Date: Dec. 19, 2018

(30) Foreign Application Priority Data
Jun. 20, 2016 (JP) 2016-121585

(51) Int. Cl. H01L 21/67; H01L 21/677; B65G 43/00

(52) U.S. Cl. CPC H01L 21/67259; B65G 2203/042; B65G 43/00; H01L 21/67706

(57) ABSTRACT

There is provided a transfer device, comprising: a transfer part configured to transfer a target object; a transfer path having a plurality of transfer positions at which the transfer part transfers the target object while moving along one direction; a driving mechanism of a belt driving type configured to move the transfer part along the transfer path by a timing belt arranged in the one direction; a position sensor configured to generate a signal when the transfer part reaches a predetermined position corresponding to each of the transfer positions; and a controller configured to control the transfer part. The controller has coordinates of a position of the transfer part, and is configured to correct position data of the transfer part in the coordinate system of the controller based on the signal each time the controller receives the signal from the position sensor.

### TECHNICAL FIELD

The present disclosure relates to a transfer device and a transfer method for transferring a target object, and an inspection system.

### BACKGROUND

In the manufacturing process of a semiconductor device, an IC chip formed on a semiconductor wafer is electrically inspected. As an inspection device that performs such electrical inspection, a probe device that performs the electrical inspection by bringing a probe into contact with electrodes of a semiconductor element formed on a semiconductor wafer is generally used.

In order to efficiently perform such electrical inspection on a large number of semiconductor wafers, an inspection system has been proposed, in which a plurality of probe devices (inspection devices) is arranged and semiconductor wafers received in a receiving vessel such as an FOUP are transferred to each of the probe devices by a transfer device (for example, Patent Document 1).

In order to further improve the efficiency of electrical inspection of semiconductor wafers, recently, there has also been a demand for an inspection system in which as many as 10 to 15 probe devices (inspection devices) are arranged in a horizontal direction.

### PRIOR ART DOCUMENTS

### Patent Documents

Patent Document 1: Japanese laid-open publication No. 2013-254812

As the number of inspection devices is increased in this way, since a loader performing transferring the wafers in the transfer device that transfers the semiconductor wafers has a moving distance (stroke) of about ten meters at the longest in the horizontal direction, it is technically difficult to apply a ball screw drive or a linear motor drive that are generally used as a driving method.

On the other hand, a belt driving method using a timing belt is suitable for transfer of such a long moving distance.

However, when the timing belt becomes longer by about ten meters, there is an influence of slackness or elongation, and when controlling the position of the loader, there may be a case where a deviation occurs between the position of the loader based in the coordinate system of a software and the actual position of the loader, making it impossible to accurately transfer the semiconductor wafers as target objects.

The present disclosure provides some embodiments of a transfer device and a transfer method capable of transferring a target object at an accurate position even when a belt driving method using a timing belt is adopted, and an inspection system using such a transfer device.

### SUMMARY

According to a first aspect of the present disclosure, there is provided a transfer device, including: a transfer part configured to transfer a target object; a transfer path having a plurality of transfer positions at which the transfer part transfers the target object while moving along one direction; a driving mechanism of a belt driving type configured to move the transfer part along the transfer path by a timing belt arranged in the one direction; a position sensor configured to generate a signal when the transfer part reaches a predetermined position corresponding to each of the transfer positions; and controller configured to control the transfer part, wherein the controller has coordinates of a position of the transfer part, and is configured to correct position data of the transfer part in a coordinate system of the controller based on the signal each time the controller receives the signal from the position sensor.

It is preferable that the transfer device further includes a positioning mechanism configured to mechanically position the transfer part at each of the plurality of transfer positions when the transfer part reaches near each of the plurality of transfer positions.

The transfer device can be configured to further include a flag installed at the predetermined position corresponding to each of the plurality of transfer positions of the transfer path, wherein the position sensor is installed in the transfer part, and when the position sensor reaches the flag, the signal is generated from the position sensor.

The position sensor includes a plurality of position sensors arranged in a direction orthogonal to the one direction.

The transfer part is connected to the timing belt via a connection member, and the connection member is connected to an upper end side of the timing belt. The transfer device further includes a cable duct configured to receive cables connected to the transfer part; and a roller part configured to support an upper end side of the cable duct.

According to a second aspect of the present disclosure, there is provided a transfer method using a transfer device including a transfer part configured to transfer a target object, a transfer path having a plurality of transfer positions at which the transfer part transfers the target object while moving along one direction, a driving mechanism of a belt driving type configured to move the transfer part along the transfer path by a timing belt arranged in the one direction, a position sensor configured to generate a signal when the transfer part reaches a predetermined position corresponding to each of the transfer positions and a controller configured to control the transfer part, the method including: generating the signal when the transfer part reaches the predetermined position corresponding to each of the plurality of transfer positions; and correcting position data of the transfer part in a coordinate system of the controller based on the signal each time the controller receives the signal from the position sensor.

According to a third aspect of the present disclosure, there is provided an inspection system, including: an inspection unit having a plurality of inspection devices arranged in one direction and configured to electrically inspect an target object to be inspected; and a transfer device configured to transfer the target object to the plurality of inspection devices, wherein the transfer device includes: a transfer part configured to transfer the target object to the plurality of inspection devices; a transfer path having a plurality of transfer positions at which the target object is transferred between the transfer part and each of the inspection devices while the transfer part is moved along one direction; a driving mechanism of a belt driving type configured to move the transfer part along the transfer path by a timing belt arranged in the one direction; a position sensor configured to generate a signal when the transfer part reaches a predetermined position corresponding to each of the plurality of transfer positions; and a controller configured to control the transfer part, wherein the controller has coordinates of a position of the transfer part, and is configured to correct position data of the transfer part in a coordinate system of the controller based on the signal each time the controller receives the signal from the position sensor.

According to the present disclosure, when the transfer part is moved by a driving mechanism of a belt driving type in which the transfer part is moved using a timing belt along the transfer path having a plurality of transfer positions for transferring the target object by the transfer part by moving the transfer part along one direction, and reaches a predetermined position corresponding to each of the transfer positions, position data of the transfer part in a coordinate system of the controller is corrected based on a signal each time the controller receives the signal generated from the sensor. Therefore, by properly correcting the positional deviation in the moving direction of the transfer part, it is possible to set the transfer position with high accuracy and to perform accurate transfer of the target object. In addition, since the position in the coordinate system of the controller is corrected based on the signals detected by the position sensors at the plurality of transfer positions, the stroke of the transfer part in the moving direction is subdivided, and even if a transfer error occurs, the error does not become large.

### BRIEF DESCRIPTION OF DRAWINGS

FIG. 1 is a plan view illustrating a schematic configuration of an inspection system according to one embodiment of the present disclosure.

FIG. 2 is a perspective view illustrating a driving mechanism in a transfer device of the inspection system in FIG. 1.

FIG. 3 is a view illustrating a connection state of a timing belt and a connection member in the driving mechanism in FIG. 2.

FIG. 4 is a side view illustrating an arrangement state of a sensor part and a flag part.

FIG. 5 is a cross-sectional view illustrating a positional relationship between position sensors and flags.

FIG. 6 is a side view illustrating a cable duct used in the transfer device.

FIG. 7 is a block diagram illustrating a controller used in the inspection system in FIG. 1.

FIG. 8 is a block diagram illustrating a main part of the controller.

FIG. 9 is a view illustrating a deviation of a transfer position.

FIG. 10 is a flowchart illustrating a flow of position control by a transfer controller.

FIG. 11 is an explanatory view illustrating position correction of a transfer position.

FIG. 12 is a schematic view illustrating a positioning mechanism.

FIG. 13A is a view illustrating a positioning operation by the positioning mechanism in FIG. 12.

FIG. 13B is a view illustrating a positioning operation by the positioning mechanism in FIG. 12.

FIG. 13C is a view illustrating a positioning operation by the positioning mechanism in FIG. 12.

FIG. 14 is a view illustrating slackness of the timing belt.

FIG. 15 is a view illustrating a state where a connection member is connected to a lower end side of the timing belt.

FIG. 16 is a view illustrating a state of a cable duct when a moving stroke of the loader in an X direction becomes longer.

### DETAILED DESCRIPTION

Embodiments of the present disclosure will now be described in detail with reference to the accompanying drawings.

### <Configuration of the Inspection System>

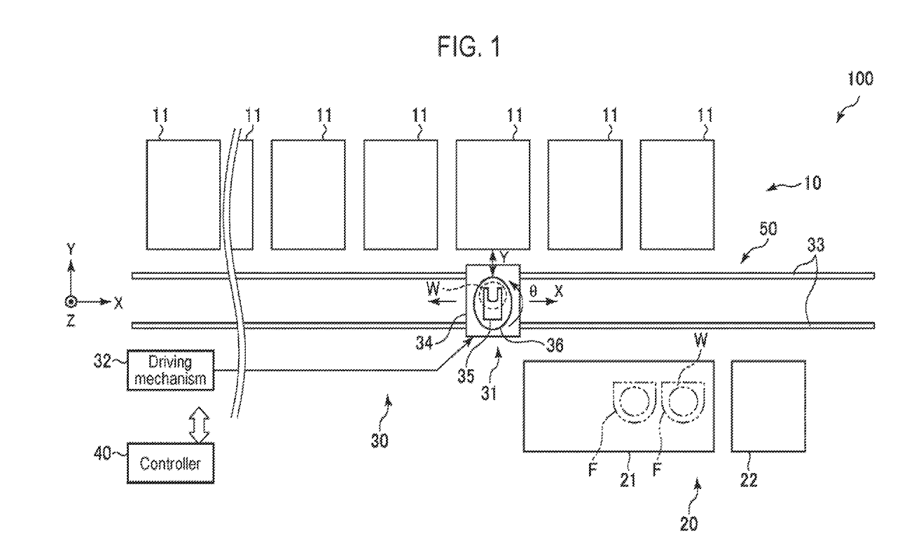

FIG. 1 is a plan view illustrating a schematic configuration of an inspection system according to one embodiment of the present disclosure. The inspection system 100 serves to electrically inspect a semiconductor wafer (hereinafter, simply referred to as a “wafer”) W as an object to be inspected, and includes an inspection unit 10, a loading/unloading unit 20, a transfer device 30, and a controller 40.

The inspection unit 10 has a plurality of, for example, about 10 to 15 inspection devices 11, which are arranged in an X direction in the drawing. Each of the inspection devices 11 is configured as a probe device, and has a housing and a wafer loading table installed therein, in which a probe card having a plurality of probe needles (contacts) is installed. The wafer loading table is configured to move the wafer loaded thereon in the X, Y, Z and θ directions, and is moved such that the probe needles of the probe card are brought into contact with electrodes of a semiconductor device formed on the wafer to perform electrical inspection of the wafer W by a tester through a test head.

The loading/unloading unit 20 has a loading/unloading stage part 21 having a plurality of loading/unloading stages for loading/unloading the wafer W, the probe card or the like, and a pre-alignment part 22 for pre-aligning the wafer W. For example, an FOUP F, which is a wafer receiving vessel, is mounted on the loading/unloading stage. In addition, the loading/unloading unit 20 may have a needle trace inspection device for performing needle trace inspection on the wafer after the inspection, or the like.

The transfer device 30 has a loader (transfer part) 31 for transferring the wafer W to the plurality of inspection devices 11 of the inspection unit 10, a driving mechanism 32 for moving the loader 31 along a transfer path 50 in the X direction which is an arrangement direction of the inspection devices 11, and an LM guide 33 for guiding the loader 31 in the X direction.

The loader 31 has a transfer base 34 that can move on the LM guide 33 in the X direction, a transfer arm 35 which supports the wafer W and can move in the Y direction, the Z direction (vertical direction), and the θ direction (rotation direction) with respect to the transfer base 34, an arm driving mechanism (not shown) for driving the transfer arm 35, and a cover member 36 for covering the wafer W on the transfer arm 35 in a retracting state. A drying gas is introduced into the cover member 36. The cover member 36 is configured to rotate in the θ direction together with the transfer arm 35.

In the transfer device 30, while the entire loader 31 is moved in the X direction by the driving mechanism 32, with the transfer arm 35, the wafer W before inspection is discharged from the FOUP on the loading/unloading stage and is transferred to the pre-alignment part 22, the wafer W after the pre-alignment is transferred to a predetermined inspection device 11, and the wafer W after the inspection is accepted from the predetermined inspection device 11 and is received in the FOUP. The number of the transfer arm 35 may be one, two, or more. The loader 31 is stopped at a transfer position corresponding to each of the plurality of inspection devices 11 and the pre-alignment part 22 so that the transfer operation by the transfer arm 35 is performed at the transfer position.

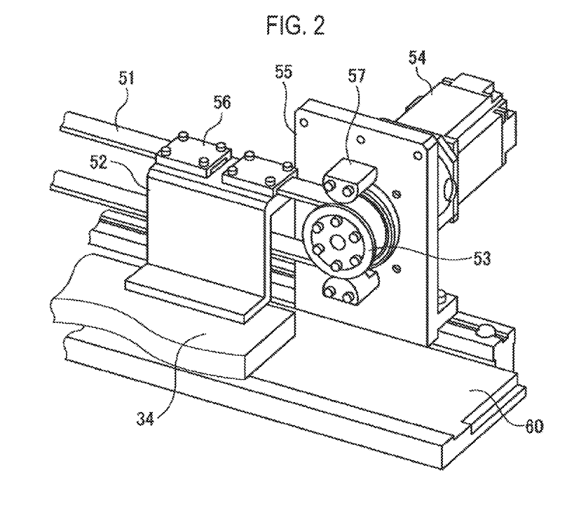

As illustrated in FIG. 2, the driving mechanism 32 is of a belt driving type, and includes a timing belt 51 in which the transfer base 34 is installed via a connection member 52, a pair of gear pulleys 53 (only a driving side is illustrated) around which the timing belt 51 is wound, and a motor 54 for driving the timing belt 51 via one of the gear pulleys 53. The gear pulley 53 and the motor 54 are fixed to a base 60 of the inspection system 100 via a support member 55. Tooth jump prevention blocks 57 are installed above and below the gear pulley 53 so as to press the timing belt 51.

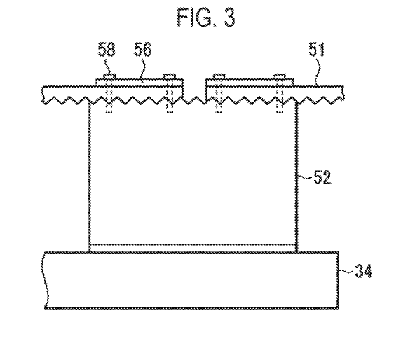

The connection member 52 is connected to an upper end side of the timing belt 51. As illustrated in FIG. 3, teeth corresponding to the inner teeth of the timing belt 51 are formed on an upper surface of the connection member 52. Furthermore, the inner portion of the timing belt 51 is fitted to the upper surface of the connection member 52 and a pressing member 56 is screwed by screws 58 from the upper side of the timing belt 51, whereby the timing belt 51 and the connection member 52 are secured.

Since the inspection unit 10 is configured by arranging about 10 to 15 inspection devices 11 in the X direction, the length of the transfer path 50 becomes a length of about ten meters and the length of the timing belt 51 between the gear pulley 53 and the other gear pulley (not shown) becomes longer. Thus, there is a risk that the upper end side and the lower end side of the timing belt 51 come into contact. However, in the present embodiment, the upper end side of the timing belt 51 and the transfer base 34 or the lower end side of the timing belt 51 are suppressed from coming into contact with each other by connecting the connection member 52 to the upper end side of the timing belt 51.

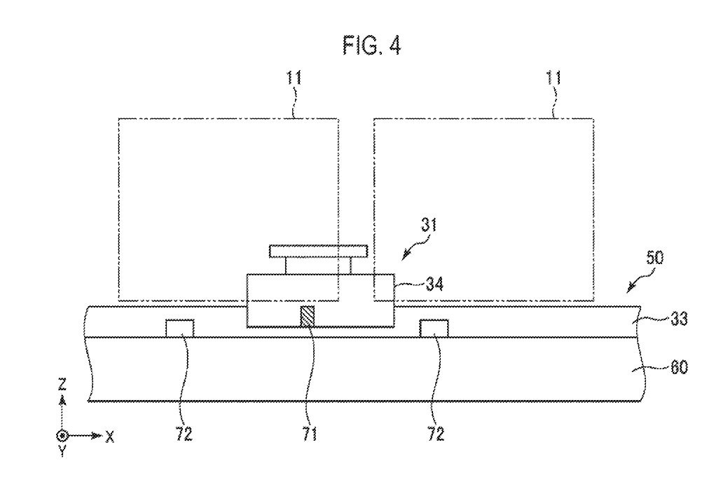

As illustrated in FIG. 4, a sensor part 71 is installed on the transfer base 34 of the loader 31. Meanwhile, flag parts 72 are installed to correspond to the sensor part 71 at positions of the base 60 corresponding to the plurality of inspection devices 11 and the pre-alignment part 22 (only portions corresponding to some of the inspection devices 11 are illustrated).

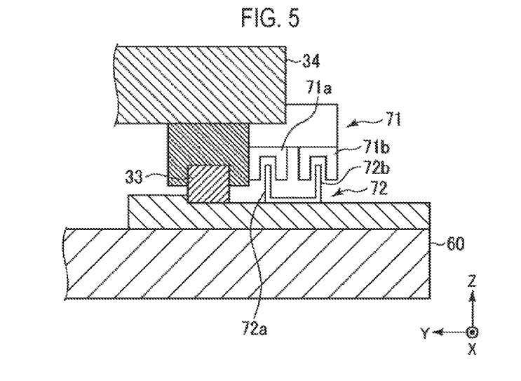

As illustrated in FIG. 5, the sensor part 71 has two position sensors 71a and 71b installed side by side in the Y direction orthogonal to the X direction at the same position in the X direction, and each of the flag parts 72 has two flags 72a and 72b installed side by side in the Y direction orthogonal to the X direction at the same position in the X direction so as to correspond to the two position sensors 71a and 71b. The position sensors 71a and 71b are configured by, for example, optical sensors formed of a light emitting element and a light receiving element, and when the loader 31 is moved in the X direction, the position sensors 71a and 71b of the sensor part 71 are configured to pass through the flags 72a and 72b of each of the flag parts 72. When the position sensors 71a and 71b pass through the flags 72a and 72b, signals are generated from the position sensors 71a and 71b. Based on the signals, as will be described later, the deviation of the transfer position of the loader 31 due to a lost motion occurring when the timing belt 51 is driven is corrected so that the wafer W can be transferred to the respective inspection devices 11 and the pre-alignment part 22 with high accuracy. The reason why the two position sensors and the two flags are installed is to reliably perform the position detection even if one position sensor fails. In this case, the number of the position sensors is not limited to two, and may be any suitable number of two or more. Also, one position sensor may be used.

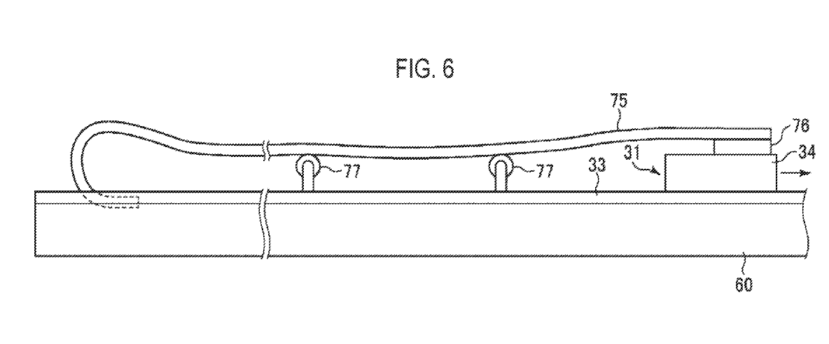

A power supply cable for feeding power to the arm driving mechanism for driving the transfer arm 35 or the like, and other cables are connected to the loader 31. As illustrated in FIG. 6, these cables are connected to a power source or the like, with the cables received in a cable duct 75. The cable duct 75 has a multi-joint structure, and is configured to be bendable at an arbitrary position corresponding to the X direction position of the loader 31. One end of the cable duct 75 is fixed to the transfer base 34 via an installation member 76, and the other end thereof is fixed to a predetermined position. Since the transfer path 50 of the loader 31 is as long as 10 to 15 m, two roller units 77 are installed on the base 60 at predetermined intervals to support the cable duct 75 so that the upper end side thereof does not come into contact with the base 60 due to “slackness” of the cable duct 75 when the moving stroke of the loader 31 becomes large. The number of roller units 77 is not limited to two, and may be any suitable number of two or more.

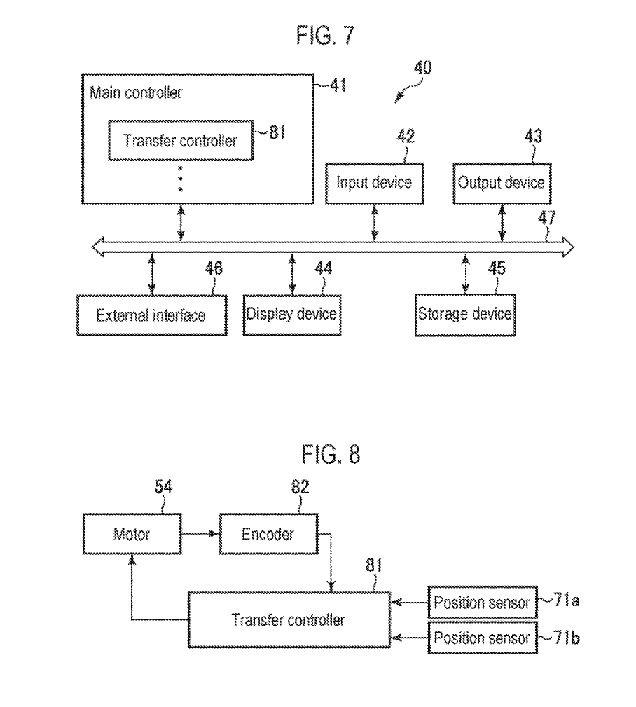

The controller 40 controls the respective components constituting the inspection system 100, for example, each inspection device 11, the transfer device 30 and the like, and as illustrated in FIG. 7, it includes a main controller 41, an input device 42 such as a keyboard, an output device 43 such as a printer, a display device 44, a storage device 45, an external interface 46, and a bus 47 for connecting these components to each other. The main controller 41 has a CPU, an RAM, and an ROM. The storage device 45 is for storing information and is configured to read information stored in a computer-readable storage medium. The storage medium is not particularly limited, and a hard disk, an optical disc, a flash memory, or the like may be used. In the main controller 41, the CPU executes a program stored in the ROM or the storage device 45 so as to perform the control of the inspection system 100. The main controller 41 has a plurality of controllers that control the respective components. One of them is a transfer controller 81 that controls the transfer device 30.

The transfer controller 81 has a coordinate system of the X direction which is the transfer direction of the loader 31, on software, and has position data in the coordinate system of the transfer position corresponding to each of the plurality of inspection devices 11 and the pre-alignment part 22. As illustrated in FIG. 8, it is configured such that a signal of an encoder 82 of the motor 54 of the driving mechanism 32 and the signals of the position sensors 71a and 71b are sent to the transfer controller 81. The transfer controller 81 is configured to confirm the position of the loader 31 in the coordinate system based on the signal from the encoder 82. Furthermore, when the position sensors 71a and 71b detect the flags 72a and 72b installed at the positions corresponding to the plurality of inspection devices 11 and the pre-alignment part 22 while moving the loader 31 in the X direction, the transfer controller 81 is configured to receive detection signals and correct the position of the loader 31 in the coordinate system in the transfer controller 81 based on the detection signals. Although the transfer controller 81 is also configured to control the driving mechanism of the transfer arm 35, details thereof will be omitted.

### <Operation of the Inspection System>

Next, an operation of the inspection system configured as described above will be described with focus on the control of the transfer device.

First, the loader 31 of the transfer device 30 is moved in the X direction to the position corresponding to the FOUP mounted on the loading/unloading stage part 21 of the loading/unloading unit 20 to discharge the wafer W before inspection from the FOUP F by the transfer arm 35. Subsequently, the loader 31 is moved in the X direction to the transfer position with respect to the pre-alignment part 22 to load the wafer W on the transfer arm 35 into the pre-alignment part 22. After the pre-alignment, the wafer W is discharged from the pre-alignment part 22 by the transfer arm 35, the loader 31 is moved in the X direction to the transfer position with respect to any one inspection device 11 to load the wafer W on the transfer arm 35 into the inspection device 11.

In the inspection device 11, the wafer W is loaded on the loading table, and the probe needles of the probe card are brought into contact with the electrodes of the semiconductor device formed on the wafer W so that the electrical inspection is performed by the tester through the test head.

After the wafer is inspected, the loader 31 is moved in the X direction to the transfer position for the inspection device 11 to discharge the wafer W after the inspection from the inspection device 11 by the transfer arm 35 and to return the wafer W to the FOUP F on the loading/unloading stage 21.

The processing as described above is continuously performed on a plurality of wafers W.

The movement of the loader 31 in the X direction at this time is performed by the driving mechanism 32. The position control of the loader 31 at this time is performed by the transfer controller 81 of the controller 40. The transfer controller 81 has coordinates corresponding to the position of the loader 31 and has position data in the coordinate system of the transfer position of the wafer W by the loader 31 with respect to each of the plurality of inspection devices 11 and the pre-alignment part 22. Then, the position control of the loader 31 in the X direction is performed using the position data.

An inspection system having a plurality of inspection devices generally uses a ball screw drive or a linear motor drive as a driving method in the X direction if the number of inspection devices is about 4 or 5, but when about 10 to 15 inspection devices 11 are arranged in the X direction and the length of the transfer path 50 is about 10 meters as in the present embodiment, it is technically difficult to apply the ball screw drive or the linear motor drive. Therefore, in the present embodiment, a belt driving method is adopted as the driving mechanism 32 for driving the loader 31 in the X direction.

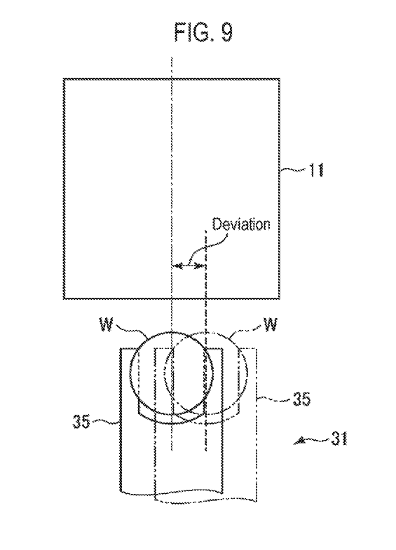

However, when the loader 31 is transferred over a long distance reaching about 10 meters by the belt driving method, there is an influence of lost motion due to slackness, elongation or the like of the timing belt 51. Thus, the position in the coordinate system of the transfer controller 81 and the actual position of the loader 31 may deviate from each other. Therefore, the transfer position in the coordinate system of the loader 31 with respect to the inspection device 11 or the pre-alignment part 22 may deviate from the original transfer position, there is a possibility of trouble in the transfer of the wafer W due to a deviation of the transfer arm 35 as illustrated in FIG. 9.

Therefore, in the present embodiment, the position sensors 71a and 71b are installed on the transfer base 34 of the loader 31 so that the coordinates of the transfer controller 81 are corrected based on the actual positions detected by the position sensors 71a and 71b.

That is, the flags 72a and 72b are respectively installed at predetermined positions corresponding to the plurality of inspection devices 11 and the pre-alignment part 22, and each time the position sensors 71a and 71b pass through the flags 72a and 72b during the movement of the loader 31 in the X direction, the transfer controller 81 receives a signal indicating it and corrects the position data of the loader 31 in the coordinate system in the transfer controller 81 based on the signal to correct the deviation of the transfer position.

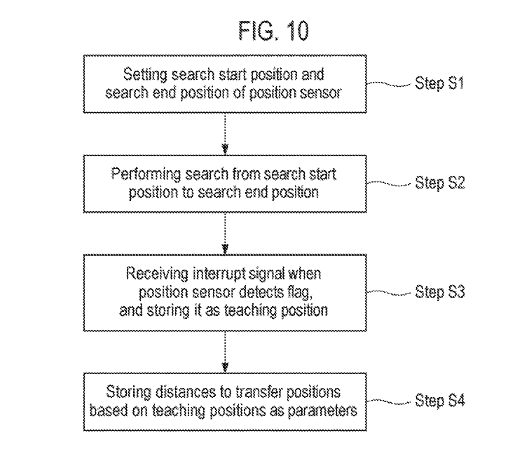

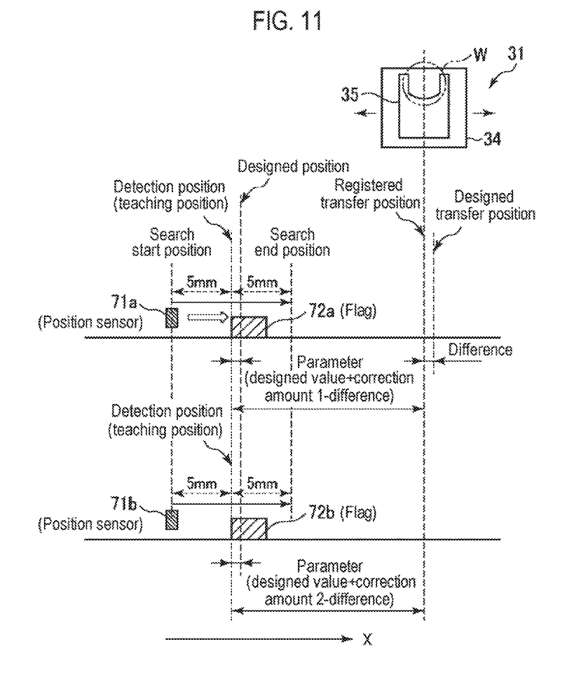

The position control by the transfer controller 81 at this time will be specifically described. FIG. 10 is a flowchart illustrating a flow at that time, and FIG. 11 is an explanatory view illustrating position correction of the transfer position.

First, a search start position and a search end position of the position sensors 71a and 71b are set (step S1). The search start position and the search end position at this time are set to, for example, positions of 5 mm before and after the flags 72a and 72b, as illustrated in FIG. 11.

Subsequently, the loader 31 is moved in the X direction, and search is performed by the position sensors 71a and 71b from the search start position to the search end position (step S2).

Then, when the position sensors 71a and 71b detect the flags 72a and 72b, interruption signals are received and positions thereof are stored as teaching positions (step S3).

Next, distances to the transfer position using the teaching positions as a reference are stored as parameters (step S4).

At this time, due to the influence of deflection or elongation of the timing belt, a deviation occurs between the loader position in the coordinate system of the transfer controller 81 and the actual loader position, but the deviation is corrected by correcting the position in the coordinate system using the teaching positions based on actual detection signals of the position sensors 71a and 71b as a reference. That is, as illustrated in FIG. 11, the deviation of the designed position which is the position in the coordinate system of the software is corrected by using the detection positions (teaching positions) actually detected by the position sensors 71a and 71b as a reference (correction amount 1 and correction amount 2). Then, the distances from the teaching positions to the transfer position are stored as the parameters. At this time, the designed transfer position is corrected based on a difference corresponding to the correction value 1 and the correction value 2, and the corrected transfer position is stored and registered (registered transfer position). The parameter corresponding to the position sensor 71a is (designed value+correction value 1-difference), and the parameter corresponding to the position sensor 71b is (designed value+correction value 2-difference).

If the interruption signal of one of the position sensors 71a and 71b is not detected, the interruption signal of the other position sensor is used and a message of a failure of the position sensor which is not detected is issued. In addition, even when the signal detection positions of both position sensors deviate, a message is issued.

In this manner, the loader position in the coordinate system in the transfer controller 81 is corrected based on the positions where the position sensors 71a and 71b actually detect the flags 72a and 72b. Thus, a transfer error (position deviation) in the X direction can be appropriately corrected to set the transfer position of the loader 31 with high accuracy and to accurately transfer the wafer W as the target object. In addition, since the position in the coordinate system of the transfer controller 81 is corrected each time the position sensors 71a and 71b detect the flags 72a and 72b in the transfer position of each of the plurality of inspection devices 11 and the pre-alignment part 22, the stroke in the X direction is subdivided, whereby, even if a transfer error occurs, the error does not become large.

Furthermore, by installing the two position sensors 71a and 71b, even when one position sensor is damaged, it is not necessary to stop the inspection system, which does not lower the device operation rate.

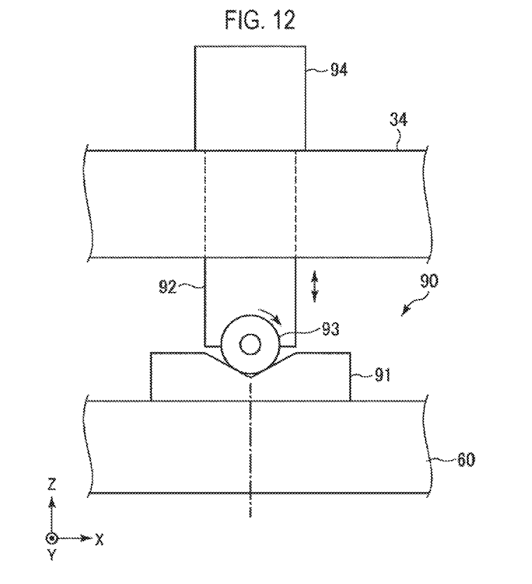

In order to more accurately set the transfer position, it is preferable to install a positioning mechanism as illustrated in FIG. 12.

This positioning mechanism 90 has a V block 91 fixed to an upper surface of the base 60, a wedge member 92 which has a roller 93 fitted to a V-shaped groove of the V block 91 and being rotatable, at a leading end thereof, and which is installed on the transfer base 34 of the loader 31 so as to be moved up and down, and a driving part 94 for moving the wedge member 92 up and down. The positioning mechanism 90 serves to set the transfer position of the loader 31 with high accuracy, and to mechanically position the loader 31 at an accurate transfer position by fitting the roller 93 of the wedge member 92 to the V-shaped groove of the V block 91. At this time, the position where the roller 93 is fitted to the V-shaped groove is a position corresponding to a transfer position with physically high accuracy in advance.

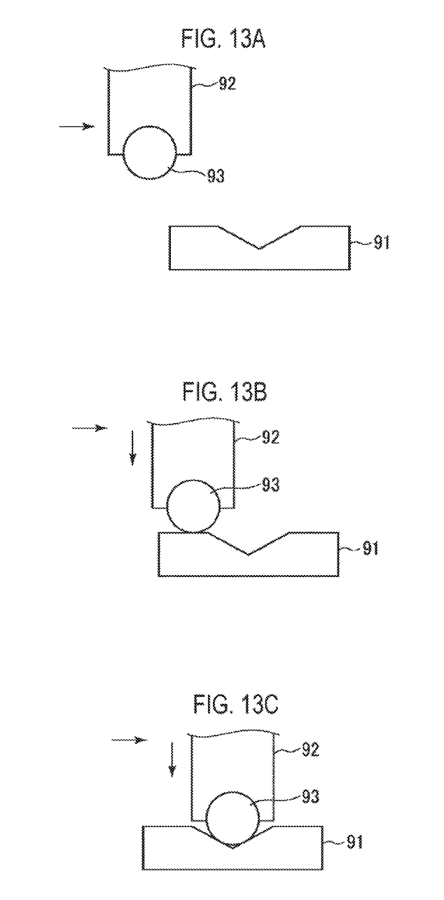

The operation of the positioning mechanism 90 is, for example, as illustrated in FIGS. 13A to 13C. In FIG. 13A, the loader 31 is in a state before reaching the transfer position, and the wedge member 92 is retracted above the V block 91. The loader 31 is transferred in the X direction, and lowers the wedge member 92 at a timing when the wedge member 92 reaches the V block 91, as illustrated in FIG. 13B. The loader 31 is stopped at the registered transfer position described above according to a command from the transfer controller 81, but there is a possibility that this registered transfer position slightly deviates from the actual transfer position.

At this time, even if the loader 31 is stopped at a position slightly deviated from the actual transfer position, as illustrated in FIG. 13C, the roller 93 is moved along the V-shaped groove so that the loader 31 can be accurately positioned at the actual transfer position. Thus, it is possible to realize highly accurate positioning.

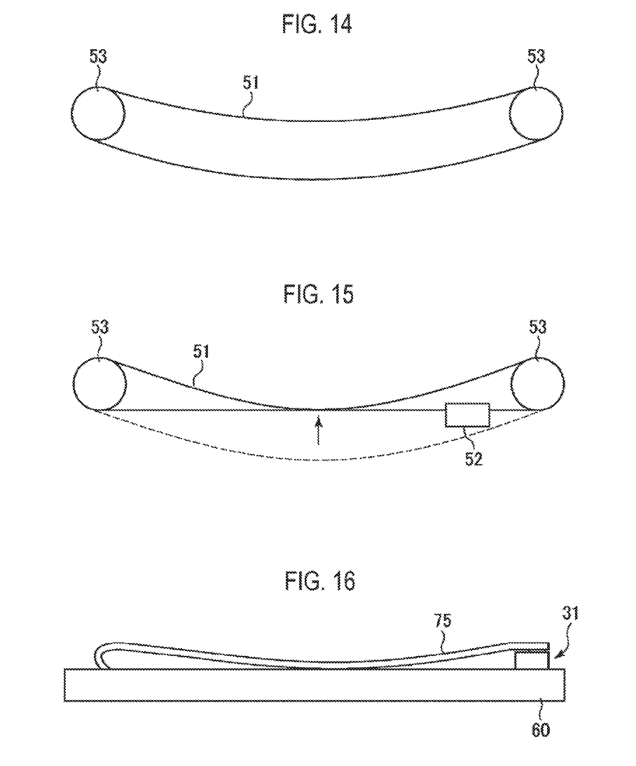

Furthermore, in the transfer device 30, since the belt driving method is adopted as the driving method of the driving mechanism 32 for moving the loader 31 along the transfer path 50 in the X direction, when the length of the transfer path 50 becomes longer by about ten meters as in the present embodiment, the timing belt also becomes longer, and as illustrated in FIG. 14, the slackness of the timing belt 51 is increased. Conventionally, the connection member 52 that connects the transfer base 34 to the timing belt 51 is often connected to the lower end side of the timing belt 51. However, in the case where the transfer stroke is long, if the connection member 52 is connected to the lower end side of the timing belt 51, as illustrated in FIG. 15, when the loader 31 is moved in the X direction, the lower end side of the timing belt 51 is raised up and the upper end side and the lower end side of the timing belt 51 may come into contact with each other. In the present embodiment, since the connection member 52 is connected to the upper end side of the timing belt 51, the upper end side and the lower end side of the timing belt 51 can be suppressed from coming into contact with each other. Furthermore, due to the deflection of the timing belt 51 by the long stroke, the lower end side of the timing belt 51 may come into contact with the base 60, but this can be solved by raising the position of the gear pulley 53 to a position in consideration of the deflection of the timing belt 51. By preventing the timing belt 51 from coming into contact with another place or by preventing the upper end side and the lower end side of the timing belt 51 from coming into contact with each other in this way, it is possible to prevent dust generation and to stably run the loader 31. In addition, it is possible to suppress an undesirable tension from being applied to the timing belt 51, and to realize more high accurate position control.

Furthermore, when the moving stroke of the loader 31 in the X direction becomes longer as the transfer path 50 of the loader 31 in the X direction is as long as 10 to 15 m, as illustrated in FIG. 16, the “amount of sagging” on the upper end side of the cable duct 75 is increased, and for example, if the moving stroke of the loader 31 in the X direction is about 9 m, the cable duct 75 may come into contact with the base 60. On the other hand, in the present embodiment, since the two roller units 77 for supporting the cable duct 75 are installed on the base 60, even when the moving stroke of the loader 31 is large, the cable duct 75 can be prevented from coming into contact with the base 60. Thus, it is possible to prevent dust generation caused by the cable duct 75 coming into contact with the base 60, and to stably run the loader 31.

### OTHER APPLICATIONS

Furthermore, the present disclosure is not limited to the aforementioned embodiment but may be differently modified within the scope of the spirit of the present disclosure. For example, in the aforementioned embodiment, there has been described an example in which the position sensors are installed on the loader side, but the position sensors may be installed at each transfer position on the base side.

In addition, in the aforementioned embodiment, the optical sensors formed of the light emitting element and the light receiving element are exemplified as the position sensors, but the present disclosure is not limited thereto and other position sensors such as a proximity sensor, a contact type sensor, or the like may be used.

Moreover, in the aforementioned embodiment, there has been described a case where the transfer device is applied to the inspection system. However, the present disclosure is not limited to the inspection system and may be applied to various systems as long as the transfer part is moved by a belt driving method using a timing belt.

Furthermore, in the aforementioned embodiment, there has been described an example in which the probe device is exemplified as the inspection device, but the inspection device is not limited to the probe device.

Moreover, in the aforementioned embodiment, there has been described an example in which the semiconductor wafer is exemplified as the target object, but the target object is not limited to the semiconductor wafer.

### EXPLANATION OF REFERENCE NUMERALS

10: inspection unit, 20: loading/unloading unit, 22: pre-alignment part, 30: transfer device, 31: loader, 32: driving mechanism, 33: LM guide, 34: transfer base, 35: transfer arm, 40: controller, 41: main controller, 50: transfer path, 51: timing belt, 52: connection member, 53: gear pulley, 54: motor, 55: support member, 60: base, 71: sensor part, 71a, 71b: position sensor, 72: flag part, 72a, 72b: flag, 75: cable duct, 77: roller unit, 81: transfer controller, 90: positioning mechanism, 91: V-block, 92: wedge member, 93: roller, 100: inspection system, W: semiconductor wafer (object to be transferred)

1. A transfer device, comprising:
a transfer part configured to transfer a target object;
a transfer path having a plurality of transfer positions at which the transfer part transfers the target object while moving along one direction;
a driving mechanism of a belt driving type configured to move the transfer part along the transfer path by a timing belt arranged in the one direction;
a position sensor configured to generate a signal when the transfer part reaches a predetermined position corresponding to each of the transfer positions;
a flag installed at a predetermined position corresponding to each of the plurality of transfer positions of the transfer path; and
a controller configured to control the transfer part,
wherein the position sensor is installed in the transfer part, and when the position sensor moves together with the transfer part and reaches the flag, the signal is generated from the position sensor,
wherein the controller has coordinates of a position of the transfer part, and is configured to correct position data of the transfer part in a coordinate system of the controller based on the signal each time the controller receives the signal from the position sensor.

2. The device of claim 1, further comprising a positioning mechanism configured to mechanically position the transfer part at each of the plurality of transfer positions when the transfer part reaches near each of the plurality of transfer positions.

3. (canceled)

4. The device of claim 1, wherein the position sensor includes a plurality of position sensors arranged in a direction orthogonal to the one direction.

5. The device of claim 1, wherein the transfer part is connected to the timing belt via a connection member, and the connection member is connected to an upper end side of the timing belt.

6. The device of claim 1, further comprising:
a cable duct configured to receive cables connected to the transfer part; and
a roller part configured to support an upper end side of the cable duct.

7. A transfer method using a transfer device including a transfer part configured to transfer a target object, a transfer path having a plurality of transfer positions at which the transfer part transfers the target object while moving along one direction, a driving mechanism of a belt driving type configured to move the transfer part along the transfer path by a timing belt arranged in the one direction, a position sensor installed in the transfer part, a flag installed at a predetermined position corresponding to each of the transfer positions of the transfer path and a controller configured to control the transfer part, the method comprising:
generating a signal from the position sensor that the transfer part reaches the predetermined position corresponding to each of the plurality of transfer positions when the position sensor moves together with the transfer part and reaches the flag; and
correcting position data of the transfer part in a coordinate system of the controller based on the signal each time the controller receives the signal from the position sensor.

8. The method of claim 7, wherein, when the transfer part reaches near each of the plurality of transfer positions, the transfer part is mechanically positioned at each of the plurality transfer positions.

9. An inspection system, comprising:
an inspection unit having a plurality of inspection devices arranged in one direction and configured to electrically inspect an target object to be inspected; and
a transfer device configured to transfer the target object to the plurality of inspection devices,
wherein the transfer device includes:
a transfer part configured to transfer the target object to the plurality of inspection devices;
a transfer path having a plurality of transfer positions at which the target object is transferred between the transfer part and each of the inspection devices while the transfer part is moved along one direction;
a driving mechanism of a belt driving type configured to move the transfer part along the transfer path by a timing belt arranged in the one direction;
a position sensor configured to generate a signal when the transfer part reaches a predetermined position corresponding to each of the plurality of transfer positions;
a flag installed at a predetermined position corresponding to each of the plurality of transfer positions of the transfer path; and
a controller configured to control the transfer part,
wherein the position sensor is installed in the transfer part, and when the position sensor and the transfer part reach the flag, the signal is generated from the position sensor,
wherein the controller has coordinates of a position of the transfer part, and is configured to correct position data of the transfer part in a coordinate system of the controller based on the signal each time the controller receives the signal from the position sensor.

10. The system of claim 9, further comprising a positioning mechanism configured to mechanically position the transfer part at each of the plurality of transfer positions when the transfer part reaches near each of the plurality of transfer positions.

11. (canceled)

12. The system of claim 9, wherein the position sensor includes a plurality of position sensors arranged in a direction orthogonal to the one direction.

13. The system of claim 9, wherein the transfer part is connected to the timing belt via a connection member, and the connection member is connected to an upper end side of the timing belt.

14. The system of claim 9, further comprising:
a cable duct configured to receive cables connected to the transfer part; and
a roller part configured to support an upper end side of the cable duct.
